(19) United States
(12) Patent Application Publication
(10) Pub. No.: US 2024/0161839 A1
(43) Pub. Date: May 16, 2024

(54) MEMORY DEVICE FOR PERFORMING PROGRAM OPERATION AND METHOD OF OPERATING THE SAME

(71) Applicant: SK hynix Inc., Icheon-si Gyeonggi-do (KR)

(72) Inventors: Hyung Jin CHOI, Icheon-si Gyeonggi-do (KR); Gwi Han KO, Icheon-si Gyeonggi-do (KR)

(73) Assignee: SK hynix Inc., Icheon-si Gyeonggi-do (KR)

(21) Appl. No.: 18/193,474

(22) Filed: Mar. 30, 2023

(30) Foreign Application Priority Data
Nov. 11, 2022 (KR) 10-2022-0150629

(51) Int. Cl. G11C 16/34; G11C 16/10; G11C 16/12

(52) U.S. Cl. CPC G11C 16/3454; G11C 16/102; G11C 16/12

(57) ABSTRACT

A memory device, and a method of operating the same, includes a plurality of memory cells configured to be programmed to any one of a plurality of program states, a peripheral circuit configured to perform a plurality of program loops on the plurality of memory cells, and a program operation controller. The program operation controller is configured to control the peripheral circuit such that a verify operation for a second program state is performed from a second program loop after a verify operation for a first program state performed from a first program loop passes, wherein the first program loop is performed before the second program loop.

### CROSS-REFERENCE TO RELATED APPLICATION

The present application claims priority under 35 U.S.C. § 119(a) to Korean patent application number 10-2022-0150629 filed on Nov. 11, 2022, in the Korean Intellectual Property Office, the entire disclosure of which is incorporated by reference herein.

### BACKGROUND

### 1. Technical Field

Various embodiments of the present disclosure relate to a semiconductor device, and more particularly to a memory device for performing a program operation and a method of operating the memory device.

### 2. Related Art

A storage device is a device which stores data under the control of a host device such as a computer or a smartphone. The storage device may include a memory device in which data is stored and a memory controller which controls the memory device. The memory device may include a nonvolatile memory device.

The nonvolatile memory device may be a memory device in which stored data is retained even when the supply of power is interrupted. The nonvolatile memory device may include, for example, read only memory (ROM), programmable ROM (PROM), electrically programmable ROM (EPROM), electrically erasable and programmable ROM (EEPROM), and flash memory.

Meanwhile, a program operation of the memory device may include a blind verify operation. The blind verify operation may be an operation in which a verify operation for each program state is performed from a program loop set for each program state. In this case, before the program loop set for a specific program state, a verify operation for the corresponding program state may be skipped. When the verify operation for the specific program state passes earlier than expected, a verify operation is not performed before a program loop set for a next program state, and thus an abnormal phenomenon in which program voltages are successively applied may occur.

### SUMMARY

Various embodiments of the present disclosure are directed to a memory device having improved program operation performance and a method of operating the memory device.

An embodiment of the present disclosure may provide for a memory device. The memory device may include a plurality of memory cells configured to be programmed to any one of a plurality of program states, a peripheral circuit configured to perform a plurality of program loops on the plurality of memory cells, and a program operation controller configured to control the peripheral circuit such that a verify operation for a first program state among the plurality of program states is performed. The verify operation for the first program state is performed from a first program loop of the plurality of program loops, the verify operation for the second program state is performed from a second program loop of the plurality of program loops after the verify operation for the first program state has passed, and the second program loop is performed after the first program loop.

An embodiment of the present disclosure may provide for a method of operating a memory device. The method may include applying a program voltage to a plurality of memory cells in a first program loop, and in response to a verify operation in the first program loop passing for a first program state among a plurality of program states distinguished based on threshold voltages, applying a verify voltage for verifying a second program state scheduled to be performed in a second program loop, among the plurality of program states, to the plurality of memory cells.

An embodiment of the present disclosure may provide for a memory device. The memory device may include a plurality of memory cells configured to be programmed to any one of a plurality of program states, a peripheral circuit configured to perform a plurality of program loops on the plurality of memory cells, and a program operation controller configured to control the peripheral circuit such that a verify operation for a second program state having a threshold voltage higher than a threshold voltage for a first program state among the plurality of program states is performed from a first program loop among the plurality of program loops and such that a program loop in which the verify operation for the second program state is to be performed is changed depending on whether a verify operation for the first program state has passed.

### BRIEF DESCRIPTION OF THE DRAWINGS

FIG. 1 is a diagram illustrating a memory device according to an embodiment of the present disclosure.

FIG. 2 is a diagram illustrating a program operation according to an embodiment of the present disclosure.

FIG. 3 is a diagram illustrating program states of memory cells according to an embodiment of the present disclosure.

FIG. 4 is a diagram illustrating an example of a verify operation for each program state according to an embodiment of the present disclosure.

FIG. 5 is a diagram illustrating an example of a verify operation for each program state according to an embodiment of the present disclosure.

FIG. 6 is a flowchart illustrating a method of operating a memory device according to an embodiment of the present disclosure.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms and should not be construed as being limited to the embodiments described in the specification or application. The words “first,” “second,” “third,” etc. are used to distinguish between similar components or operations and not to imply a specific number or order of the components or operations.

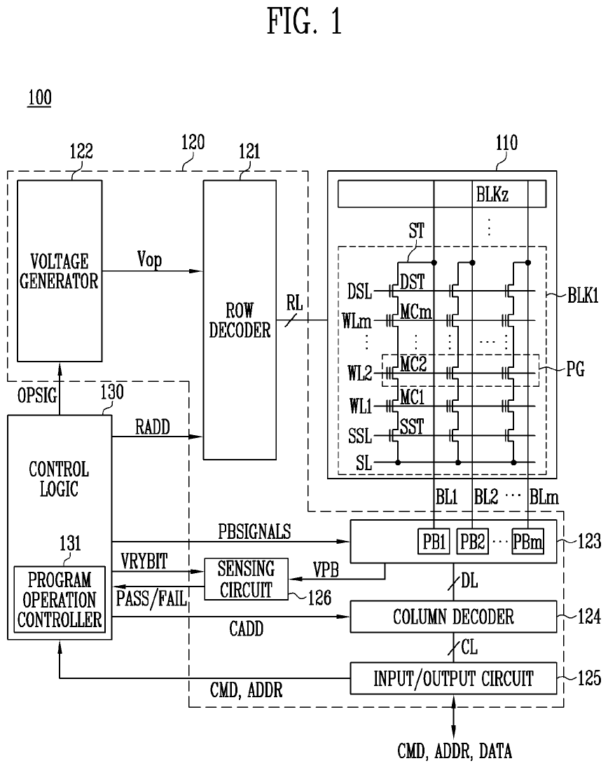

FIG. 1 is a diagram illustrating a memory device according to an embodiment of the present disclosure.

Referring to FIG. 1, a memory device 100 may include a memory cell array 110, a peripheral circuit 120, and control logic 130.

The memory cell array 110 includes a plurality of memory blocks BLK1 to BLKz.

The plurality of memory blocks BLK1 to BLKz are coupled to a row decoder 121 through row lines RL. Here, the row lines RL may include at least one source select line SSL, a plurality of word lines WL1 to WLm, and at least one drain select line DSL.

Each of the memory blocks BLK1 to BLKz may be coupled to a page buffer group 123 through bit lines BL1 to BLm. Each of the plurality of memory blocks BLK1 to BLKz may include a plurality of memory cell strings ST coupled between the bit lines BL1 to BLm and a source line SL. The bit lines BL1 to BLm may be coupled to the memory cell strings ST, respectively, and the source line SL may be coupled in common to the memory cell strings ST. Each memory cell string ST may include at least one source select transistor SST, a plurality of memory cells MC1 to MCm, and at least one drain select transistor DST which are coupled in series to each other between the source line SL and the bit lines BL1 to BLm.

Each of the memory blocks BLK1 to BLKz may include the plurality of memory cells MC1 to MCm. In an embodiment, the plurality of memory cells may be nonvolatile memory cells. Memory cells coupled to the same word line may be defined as one page (PG). Therefore, one memory block may include a plurality of pages (PG).

The peripheral circuit 120 may perform a program operation, a read operation, or an erase operation on a selected area of the memory cell array 110 under the control of the control logic 130.

The peripheral circuit 120 may include the row decoder 121, a voltage generator 122, the page buffer group 123, a column decoder 124, an input/output circuit 125, and a sensing circuit 126.

The row decoder 121 is coupled to the memory cell array 110 through the row lines RL.

The row decoder 121 may decode a row address RADD received from the control logic 130. The row decoder 121 may select at least one of the memory blocks BLK1 to BLKz according to the decoded address. Further, the row decoder 121 may select at least one word line of the selected memory block so that voltages generated by the voltage generator 122 are applied to the at least one word line according to the decoded address.

For example, during a program operation, the row decoder 121 may apply a program voltage to a selected word line and apply a program pass voltage having a level lower than that of the program voltage to unselected word lines. During a program verify operation, the row decoder 121 may apply a verify voltage to the selected word line and apply a verify pass voltage higher than the verify voltage to the unselected word lines.

The voltage generator 122 may generate a plurality of voltages using an external supply voltage provided to the memory device 100. In detail, the voltage generator 122 may generate various operating voltages Vop that are used for program, read, and erase operations in response to an operation signal OPSIG. The generated operating voltages Vop may be supplied to the memory cell array 110 by the row decoder 121.

The page buffer group 123 includes first to m-th page buffers PB1 to PBm. The first to m-th page buffers PB1 to PBm may temporarily store data received through the first to m-th bit lines BL1 to BLm in response to page buffer control signals PBSIGNALS or may sense voltages or currents of the bit lines BL1 to BLm during a read or verify operation.

In detail, during a program operation, when a program pulse is applied to a selected word line, the first to m-th page buffers PB1 to PBm may transfer data DATA, received through the input/output circuit 125, to selected memory cells through the first to m-th bit lines BL1 to BLm. Memory cells in a selected page may be programmed based on the received data DATA. Memory cells coupled to a bit line to which a program-enable voltage (e.g., a ground voltage) is applied may have increased threshold voltages. The threshold voltages of memory cells coupled to a bit line to which a program-inhibit voltage (for example, a supply voltage) is applied may be maintained. During a program verify operation, the first to m-th page buffers PB1 to PBm may read page data from the selected memory cells through the first to m-th bit lines BL1 to BLm.

The column decoder 124 may transfer data between the input/output circuit 125 and the page buffer group 123 in response to a column address CADD. For example, the column decoder 124 may exchange data with the first to m-th page buffers PB1 to PBm through data lines DL or may exchange data with the input/output circuit 125 through column lines CL.

The input/output circuit 125 may transfer commands CMD and addresses ADDR, received from a memory controller (not illustrated), to the control logic 130, or may exchange the data DATA with the column decoder 124. For example, the memory controller may generate various commands CMD and addresses ADDR required for various types of operations in response to requests received from a host or an external device, and may transfer the commands and the addresses to the input/output circuit 125.

During a read operation or a verify operation, the sensing circuit 126 may generate a reference current in response to an enable bit signal VRYBIT, and may compare a sensing voltage VPB received from the page buffer group 123 with a reference voltage generated by the reference current and then output a pass signal PASS or a fail signal FAIL.

The control logic 130 may control the peripheral circuit 120 by outputting the operation signal OPSIG, the row address RADD, the page buffer control signals PBSIGNALS, and the enable bit signal VRYBIT in response to the commands CMD and the addresses ADDR. In addition, the control logic 130 may determine whether a verify operation has passed or failed in response to the pass or fail signal PASS or FAIL.

The control logic 130 may be implemented as hardware, software, or a combination of hardware and software. For example, the control logic 130 may be a control logic circuit operating in accordance with an algorithm and/or a processor executing control logic code. In an embodiment, the control logic 130 may include a program operation controller 131. For an embodiment, the program operation controller 131 may also be an electronic circuit.

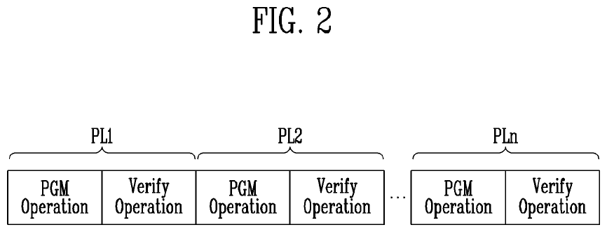

The program operation controller 131 may control a program operation of the memory device 100. The program operation will be described in detail later with reference to FIG. 2.

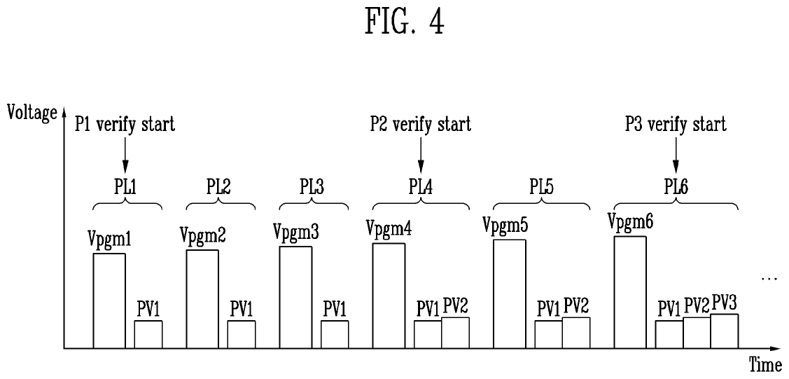

In an embodiment, the program operation controller 131 may perform a blind verify operation during the program operation. Such a blind verify operation will be described in detail later with reference to FIG. 4.

In an embodiment, the program operation controller 131 may change a program loop in which a verify operation for a second program state is to be performed, depending on whether a verify operation for a first program state, among a plurality of program states, has passed. Here, the first program state may have a threshold voltage lower than a threshold voltage in the second program state.

In an embodiment, the program operation controller 131 may control the peripheral circuit 120 so that the verify operation for the second program state is performed from a first program loop, but the verify operation for the second program state is performed from a second program loop when the verify operation for the first program state has passed. In this case, the second program loop may be a program loop performed prior to the first program loop, and may be a program loop subsequent to the program loop in which the verify operation for the first program state has passed. For example, the program operation controller 131 may determine whether the verify operation for the first program state has passed before the second program loop is performed. Furthermore, the program operation controller 131 may control the peripheral circuit 120 so that, after the verify operation for the first program state has passed, a verify voltage used to verify the first program state is not generated. Unlike this operation, the program operation controller 131 might not perform the verify operation for the second program state until the first program loop is performed when the verify operation for the first program state has not passed.

FIG. 2 is a diagram illustrating a program operation according to an embodiment of the present disclosure.

Referring to FIG. 2, the program operation of the memory device 100 may include a plurality of program loops PL1 to PLn. That is, the memory device 100 may program selected memory cells so that each of the selected memory cells has a threshold voltage corresponding to any one of a plurality of program states by performing the plurality of program loops PL1 to PLn.

Each of the plurality of program loops PL1 to PLn may include a program voltage apply operation (PGM Operation) of applying a program voltage to the memory cells and a verify operation (Verify Operation) of verifying whether the memory cells have been programmed by applying verify voltages.

For example, when the first program loop PL1 is performed, a first program pulse is applied in the program voltage apply operation (PGM Operation), after which verify voltages are sequentially applied to verify program states of a plurality of memory cells in the verify operation.

The memory cells which have passed verification using respective verify voltages may be determined to have target program states, and may then be program-inhibited in the second program loop PL2. To program the remaining memory cells other than the program-inhibited memory cells in the second program loop PL2, a second program pulse higher than the first program pulse by a unit voltage is applied. Thereafter, a verify operation may be performed in the same way as the verify operation in the first program loop PL1. In an example, the term “verify pass” indicates that each memory cell is read as an off-cell using the corresponding verify voltage.

During a verify operation, a verify voltage may be applied to a selected word line which is a word line coupled to selected memory cells, and a page buffer may determine whether the selected memory cells have passed the verify operation based on currents or voltages flowing through bit lines respectively coupled to the selected memory cells.

For example, the memory device 100 may store the states of memory cells depending on the voltages of the bit lines. Here, the state of each memory cell may be a state corresponding to any one of verify pass or verify fail. When the threshold voltage of the memory cell is higher than the verify voltage applied to the selected word line, the corresponding memory cell may be read as an off-cell, and the memory cell read as the off-cell may correspond to a verify pass state. In contrast, when the threshold voltage of the memory cell is lower than the verify voltage applied to the selected word line, the corresponding memory cell may be read as an on-cell, and the memory cell read as the on-cell may correspond to a verify fail state.

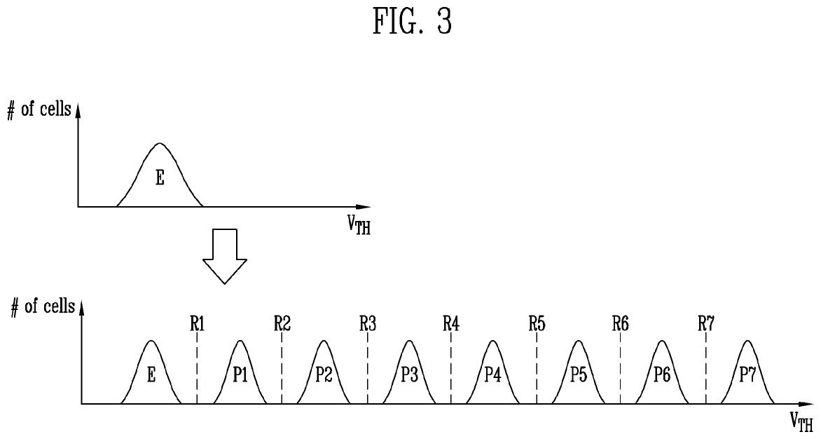

FIG. 3 is a diagram illustrating program states of memory cells according to an embodiment of the present disclosure.

In FIG. 3, for convenience of description, each of a plurality of memory cells is assumed to be a triple-level cell (TLC). However, the scope of the present disclosure is not limited thereto, and each of the plurality of memory cells may be a single-level cell (SLC), a multi-level cell (MLC), or a quad-level cell (QLC).

Referring to FIG. 3, a horizontal axis indicates threshold voltages of memory cells and a vertical axis indicates the number of memory cells. A plurality of program states may be distinguished from each other based on threshold voltages.

Selected memory cells, which are memory cells coupled to a selected word line, may have a threshold voltage distribution corresponding to an erase state E, as in a graph illustrated in the upper portion of the drawing, before a program operation is performed.

When the memory cell stores data corresponding to 3 bits, the memory cell may be programmed to have a threshold voltage corresponding to any one of an erase state E, a first program state P1, a second program state P2, a third program state P3, a fourth program state P4, a fifth program state P5, a sixth program state P6, and a seventh program state P7.

The erase state E may correspond to data ‘111’, the first program state P1 may correspond to data ‘110’, the second program state P2 may correspond to data ‘101’, the third program state P3 may correspond to data ‘100’, the fourth program state P4 may correspond to data ‘011’, the fifth program state P5 may correspond to data ‘010’, the sixth program state P6 may correspond to data ‘001’, and the seventh program state P7 may correspond to data ‘000’. However, pieces of data or binary combinations corresponding to respective program states are only examples, and may be modified in various forms.

When the program operation is terminated, each of the selected memory cells may have a threshold voltage corresponding to any one of the erase state E, the first program state P1, the second program state P2, the third program state P3, the fourth program state P4, the fifth program state P5, the sixth program state P6, and the seventh program state P7, as in a graph illustrated in the lower portion of the drawing. The memory device may read data stored in selected memory cells by performing a read operation using first to seventh read voltages R1 to R7.

The first read voltage R1 may be a read voltage for distinguishing the erase state E from the first program state P1, the second read voltage R2 may be a read voltage for distinguishing the first program state P1 from the second program state P2, the third read voltage R3 may be a read voltage for distinguishing the second program state P2 from the third program state P3, the fourth read voltage R4 may be a read voltage for distinguishing the third program state P3 from the fourth program state P4, the fifth read voltage R5 may be a read voltage for distinguishing the fourth program state P4 from the fifth program state P5, the sixth read voltage R6 may be a read voltage for distinguishing the fifth program state P5 from the sixth program state P6, and the seventh read voltage R7 may be a read voltage for distinguishing the sixth program state P6 from the seventh program state P7.

FIG. 4 is a diagram illustrating an example of a verify operation for each program state according to an embodiment of the present disclosure.

In FIG. 4, operations in first to sixth program loops PL1 to PL6, among a plurality of program loops, are illustrated. However, the scope of the present disclosure is not limited thereto, and the operations in the first to sixth program loops PL1 to PL6, described with reference to FIG. 4, may be equally applied to the remaining program loops. Also, it is assumed that a program loop corresponding to the first program state P1 is the first program loop PL1, a program loop corresponding to the second program state P2 is the fourth program loop PL4, and a program loop corresponding to the third program state P3 is the sixth program loop PL6. That is, as illustrated in FIG. 4, a verify operation for the first program state P1 may be scheduled to start from the first program loop PL1, a verify operation for the second program state P2 may be scheduled to start from the fourth program loop PL4, and a verify operation for the third program state P3 may be scheduled to start from the sixth program loop PL6.

Referring to FIG. 4, the memory device 100 may perform a blind verify operation. In detail, the memory device 100 may control the peripheral circuit 120 to perform verify operations for the plurality of program states from program loops respectively corresponding to the plurality of program states. Here, a program loop corresponding to each of the plurality of program states may be a program loop in which a verify operation for the corresponding program state starts.

In detail, the memory device 100 may perform a verify operation for the first program state P1 from the first program loop PL1.

For example, in the first program loop PL1, the memory device 100 may apply a first program voltage Vpgm1 to the plurality of memory cells, and thereafter apply a first verify voltage PV1 for verifying the first program state P1 to the plurality of memory cells.

Subsequently, in the second program loop PL2, the memory device 100 may apply a second program voltage Vpgm2 to the plurality of memory cells, and thereafter apply the first verify voltage PV1 to the plurality of memory cells.

Thereafter, in the third program loop PL3, the memory device 100 may apply a third program voltage Vpgm3 to the plurality of memory cells, and thereafter apply the first verify voltage PV1 to the plurality of memory cells.

In an embodiment, the memory device 100 may perform a verify operation for the second program state P2 from the fourth program loop PL4. For example, in the fourth program loop PL4, the memory device 100 may apply a fourth program voltage Vpgm4 to the plurality of memory cells, and thereafter apply the first verify voltage PV1 and a second verify voltage PV2 for verifying the second program state P2 to the plurality of memory cells.

Thereafter, in the fifth program loop PL5, the memory device 100 may apply a fifth program voltage Vpgm5 to the plurality of memory cells, and thereafter apply the first verify voltage PV1 and the second verify voltage PV2 to the plurality of memory cells.

In an embodiment, the memory device 100 may perform a verify operation for the third program state P3 from the sixth program loop PL6. For example, in the sixth program loop PL6, the memory device 100 may apply a sixth program voltage Vpgm6 to the plurality of memory cells, and thereafter apply the first verify voltage PV1, the second verify voltage PV2, and a third verify voltage PV3 for verifying the third program state P3 to the plurality of memory cells.

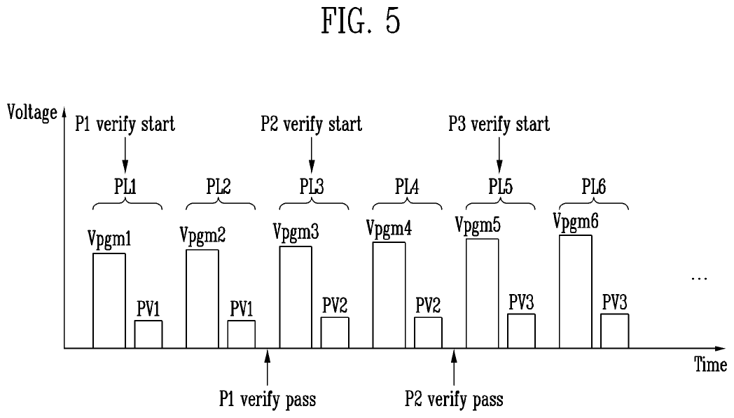

As described above, the verify operation for the second program state P2 might not be performed during a period from the first program loop PL1 to the third program loop PL3. Furthermore, the verify operation for the third program state P3 might not be performed during a period from the first program loop PL1 to the fifth program loop PL5. Meanwhile, in the following FIG. 5, a verify operation of preventing an abnormal phenomenon in which program voltages are successively applied will be described.

FIG. 5 is a diagram illustrating an example of a verify operation for each program state according to an embodiment of the present disclosure.

In FIG. 5, operations in first to sixth program loops PL1 to PL6, among a plurality of program loops, are illustrated. However, the scope of the present disclosure is not limited thereto, and the operations in the first to sixth program loops PL1 to PL6, described with reference to FIG. 5, may be equally applied to the remaining program loops. Also, it is assumed that a program loop corresponding to the first program state P1 is the first program loop PL1, a program loop corresponding to the second program state P2 is the fourth program loop PL4, and a program loop corresponding to the third program state P3 is the sixth program loop PL6. That is, a verify operation for the first program state P1 may be scheduled to start from the first program loop PL1, a verify operation for the second program state P2 may be scheduled to start from the fourth program loop PL4, and a verify operation for the third program state P3 may be scheduled to start from the sixth program loop PL6.

Referring to FIG. 5, the memory device 100 may perform a verify operation for the first program state P1 from the first program loop PL1.

For example, in the first program loop PL1, the memory device 100 may apply a first program voltage Vpgm1 to the plurality of memory cells, and thereafter apply a first verify voltage PV1 for verifying the first program state P1 to the plurality of memory cells.

Subsequently, in the second program loop PL2, the memory device 100 may apply a second program voltage Vpgm2 to the plurality of memory cells, and thereafter apply the first verify voltage PV1 to the plurality of memory cells. In an embodiment, the memory device 100 may determine whether the verify operation for the first program state P1 has passed in the second program loop PL2. As a result of the determination, when the verify operation for the first program state P1 has passed, the memory device 100 might not generate the first verify voltage PV1 from a program loop after the second program loop PL2.

In an embodiment, in the third program loop PL3, the memory device 100 may apply a third program voltage Vpgm3 to the plurality of memory cells, and thereafter apply a second verify voltage PV2 to the plurality of memory cells depending on whether the verify operation for the first program state P1 has passed. That is, because the verify operation for the first program state P1 has passed before the fourth program loop PL4 corresponding to the second program state P2 is reached, the memory device 100 may perform a verify operation for the second program state P2 from the third program loop PL3 performed before the fourth program loop PL4.

Subsequently, in the fourth program loop PL4, the memory device 100 may apply a fourth program voltage Vpgm4 to the plurality of memory cells, and thereafter apply the second verify voltage PV2 to the plurality of memory cells. In an embodiment, the memory device 100 may determine whether the verify operation for the second program state P2 has passed in the fourth program loop PL4. As a result of the determination, when the verify operation for the second program state P2 has passed, the memory device 100 might not generate the second verify voltage PV2 from a program loop after the fourth program loop PL4.

In an embodiment, in the fifth program loop PL5, the memory device 100 may apply a fifth program voltage Vpgm5 to the plurality of memory cells, and thereafter apply a third verify voltage PV3 to the plurality of memory cells depending on whether the verify operation for the second program state P2 has passed. That is, because the verify operation for the second program state P2 has passed before the sixth program loop PL6 corresponding to the third program state P3 is reached, the memory device 100 may perform a verify operation for the third program state P3 from the fifth program loop PL5 performed before the sixth program loop PL6.

Subsequently, in the sixth program loop PL6, the memory device 100 may apply a sixth program voltage Vpgm6 to the plurality of memory cells, and thereafter apply the third verify voltage PV3 to the plurality of memory cells.

Therefore, in accordance with an embodiment of the present disclosure, when a verify operation for an i-th program state has passed, a verify operation for an i+1-th program state is performed from a program loop performed before a program loop corresponding to the i+1-th program state having a threshold voltage higher than that in the i-th program state, thus improving the performance of the program operation.

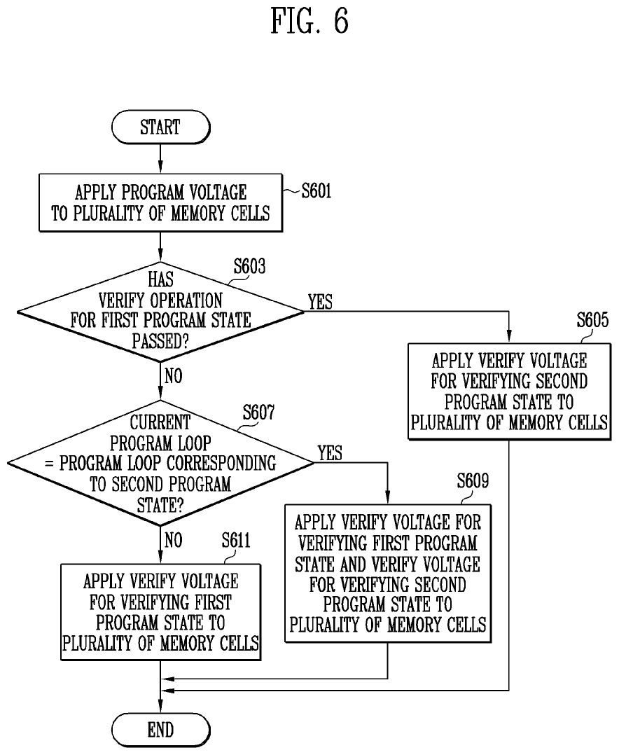

FIG. 6 is a flowchart illustrating a method of operating a memory device according to an embodiment of the present disclosure.

The method illustrated in FIG. 6 may be performed by, for example, the memory device 100 illustrated in FIG. 1.

Referring to FIG. 6, at step S601, the memory device 100 may apply a program voltage to a plurality of memory cells in a current program loop.

At step S603, the memory device 100 may determine whether a verify operation for a first program state has passed. Here, whether the verify operation for the first program state has passed may be determined in a previous program loop. For example, the memory device 100 may verify whether the verify operation for the first program state has passed based on a pass signal or a fail signal in the verify operation for the first program state, generated in the previous program loop.

In response to the case where the verify operation for the first program state has passed as a result of the determination at step S603, the memory device 100 may apply a verify voltage for verifying the second program state to the plurality of memory cells in the current program loop at step S605. Here, the second program state may have a threshold voltage higher than a threshold voltage in the first program state. That is, at step S605, the memory device 100 may perform a verify operation for the second program state in the current program loop because the verify operation for the first program state has passed even before the program loop corresponding to the second program state is reached.

On the other hand, when the verify operation for the first program state has not passed as a result of the determination at step S603, the memory device 100 may perform step S607.

At step S607, the memory device 100 may determine whether the current program loop is a program loop corresponding to the second program state.

When it is determined at step S607 that the current program loop is the program loop corresponding to the second program state, the memory device 100 may apply a verify voltage for verifying the first program state and a verify voltage for verifying the second program state to the plurality of memory cells at step S609.

On the other hand, when it is determined at step S607 that the current program loop is not a program loop corresponding to the second program state, the memory device 100 may apply the verify voltage for verifying the first program state to the plurality of memory cells at step S611.

In accordance with the present disclosure is a memory device having improved program operation performance and a method of operating the memory device.

What is claimed is:

1. A memory device, comprising:
a plurality of memory cells configured to be programmed to any one of a plurality of program states;
a peripheral circuit configured to perform a plurality of program loops on the plurality of memory cells; and
a program operation controller configured to control the peripheral circuit such that a verify operation for a first program state among the plurality of program states is performed and a verify operation for a second program state among the plurality of program states is performed,
wherein the verify operation for the first program state is performed from a first program loop of the plurality of program loops,
wherein the verify operation for the second program state is performed from a second program loop of the plurality of program loops after the verify operation for the first program state has passed, and
wherein the second program loop is performed after the first program loop.

2. The memory device according to claim 1, wherein the first program state has a threshold voltage lower than a threshold voltage of the second program state.

3. The memory device according to claim 1, wherein the first program loop and the second program loop are performed sequentially.

4. The memory device according to claim 1, wherein the program operation controller determines whether the verify operation for the first program state has passed before the second program loop is performed.

5. The memory device according to claim 4, wherein the program operation controller performs additional program loops after the first program loop and before the second program loop and does not perform the verify operation for the second program state until after the verify operation for the first program state has passed in the additional program loop immediately preceding the second program loop.

6. The memory device according to claim 1, wherein the program operation controller controls the peripheral circuit such that a verify voltage for verifying the first program state is not generated after the verify operation for the first program state has passed.

7. A method of operating a memory device, comprising:
applying a program voltage to a plurality of memory cells in a first program loop; and
in response to a verify operation in the first program loop passing for a first program state among a plurality of program states distinguished based on threshold voltages, applying a verify voltage for verifying a second program state scheduled to be performed in a second program loop, among the plurality of program states, to the plurality of memory cells.

8. The method according to claim 7, wherein the first program state has a threshold voltage lower than a threshold voltage of the second program state.

9. The method according to claim 7, wherein the second program loop is performed after the first program loop.

10. The method according to claim 7, further comprising:
before the first program loop is performed, determining whether the verify operation for the first program state has passed.

11. The method according to claim 7, wherein a verify voltage for verifying the first program state is not generated in the first program loop.

12. A memory device, comprising:
a plurality of memory cells configured to be programmed to any one of a plurality of program states;
a peripheral circuit configured to perform a plurality of program loops on the plurality of memory cells; and
a program operation controller configured to control the peripheral circuit such that a verify operation for a second program state having a threshold voltage higher than a threshold voltage for a first program state among the plurality of program states is performed from a first program loop among the plurality of program loops and such that a program loop in which the verify operation for the second program state is to be performed is changed depending on whether a verify operation for the first program state has passed.

13. The memory device according to claim 12, wherein the program operation controller controls the peripheral circuit such that, when the verify operation for the first program state has passed, the verify operation for the second program state is performed from a second program loop performed before the first program loop among the plurality of program loops.

14. The memory device according to claim 13, wherein the second program loop is a program loop performed after the verify operation for the first program state has passed.

15. The memory device according to claim 13, wherein the program operation controller controls the peripheral circuit such that, after the verify operation for the first program state has passed, a verify voltage for verifying the first program state is not generated.

16. The memory device according to claim 12, wherein the program operation controller does not perform the verify operation for the second program state until the first program loop is performed when the verify operation for the first program state has not passed.
